(19) United States
(12) Patent Application Publication
(10) Pub. No.: US 2025/0052703 A1
(43) Pub. Date: Feb. 13, 2025

(54) METHOD FOR EVALUATING THE BENDING STIFFNESS OF HIGH ASPECT RATIO NANOSIZED STRUCTURES

(71) Applicant: IMEC VZW, Leuven (BE)

(72) Inventors: XiuMei Xu, Bertem (BE); Gian Francesco Lorusso, Overijse (BE)

(21) Appl. No.: 18/799,185

(22) Filed: Aug. 9, 2024

(30) Foreign Application Priority Data
Aug. 12, 2023 (EP) 23191219.7

(51) Int. Cl. G01N 23/2251; B82Y 35/00

(52) U.S. Cl. CPC G01N 23/2251; B82Y 35/00; G01N 2223/6116

(57) ABSTRACT

Example embodiments relate to methods for evaluating the bending stiffness of high aspect ratio nanosized structures. One example method for evaluating a bending stiffness of high aspect ratio nanosized structures arranged in a plurality of test patterns produced by lithography and etching in a respective plurality of different areas of a semiconductor substrate, where each test pattern includes a regular array of the high aspect ratio nanosized structures, includes scanning the regular arrays in the plurality of test patterns by an electron beam produced according to a same set of beam conditions for each array. The method also includes deriving images of the regular arrays in the respective test patterns by electron beam microscopy. Additionally, the method includes determining from each of the images an e-beam induced collapse rate representative of a percentage of structures in each array that have collapsed under an influence of the electron beam scanning.

### CROSS-REFERENCE TO RELATED APPLICATIONS

The present application is a non-provisional patent application claiming priority to European Patent Application No. EP 23191219.7, filed Aug. 12, 2023, the contents of which are hereby incorporated by reference.

### FIELD OF THE DISCLOSURE

The present disclosure relates to semiconductor processing, in particular to the production of high aspect ratio nanometer-sized structures, and to the characterization of mechanical properties of these structures.

### BACKGROUND

As the miniaturization of structures in semiconductor processing continues, tall and narrow upstanding structures like fins or pillars are being fabricated on a wafer. These structures are referred to as high aspect ratio nanometer-sized structures, hereafter abbreviated as nanosized structures or nanostructures. For example, pillars may be produced that have a diameter in the order of a few nanometers up to a few tens of nanometers and a height in the order of 100 nm to 10 μm, i.e. the aspect ratio is higher than 10:1. Similar aspect ratios are obtainable for fin-shaped structures having a width in the order of a few nanometers or tens of nanometers. For such structures, the bending stiffness is an important mechanical property, as it determines the integrity of the structures during the various process steps they go through.

For example, in wet cleaning processes, the surface tension force exerted by the rinsing liquids can often cause the collapse of high aspect ratio nanostructures that are arranged in a regular array. This phenomenon is commonly referred to as pattern collapse. It has been established that there is a correlation between the mechanical stiffness of the structures and the pattern collapse rate, which is a value representative of the number of collapsed structures in a given array.

The determination of the bending stiffness of individual structures is possible by applying destructive methods, such as selectively removing a structure from an array by focused ion beam (FIB), then measure the force and deflection relationship in a Transmission Electron Microscopy (TEM). However, these methods have low throughput, and are not suitable for quickly assessing the mechanical properties of nanostructures produced on a substrate, for example on a process wafer of 300 mm in diameter comprising hundreds of semiconductor dies, each die comprising large quantities of high aspect ratio nanostructures arranged in a variety of patterns. Non-destructive methods also exist, for example, a mechanical model can be established using the 3D geometry obtained by scatterometry measurements to calculate the average bending stiffness of the high aspect ratio structures. However, scatterometry measurements demand a large area of approximately 40 μm size with uniform patterning, and in some cases, a mechanical model may not be readily available for structures with complex stacks and geometry.

The mechanical properties of structures having the same design dimensions can vary significantly across the wafer, as a consequence of a degree of non-uniformity of the lithography and etch techniques applied for producing the structures. It is highly desirable therefore to obtain knowledge of this variation of the mechanical properties without reverting to destructive measurement techniques and without requiring accurate 3D profile measurements of the structures in question.

### SUMMARY

The disclosure relates to methods as disclosed in the appended claims. Example embodiments enable evaluating the bending stiffness of high aspect ratio nanosized structures which are arranged in a plurality of test patterns produced by lithography and etching in a respective plurality of different areas of a semiconductor substrate. Each test pattern comprises at least one regular array of the high aspect ratio structures, i.e. an array formed of mutually identical structures with a constant gap between any pair of adjacent structures in the array, for example a rectangular or hexagonal array. The arrays are characterized by a plurality of parameters, including in-plane dimensions of the structures, their height, the material of the structures and the gap between adjacent structures in the array. With “in-plane dimensions” is meant dimensions measured in a plane parallel to the plane upon which the structures are standing, for example the diameter of pillar-shaped structures or the width of fin-shaped structures measured at mid-height of the respective structures.

The method includes scanning the arrays in the multiple test patterns by an electron beam produced according to the same set of beam conditions for each pattern, deriving images of the respective arrays by electron beam microscopy, and determining from each of the images an e-beam induced collapse rate, being a value between 0 and 1 representative of the percentage of structures in each array which have collapsed under the influence of the electron beam scanning. The e-beam induced collapse rate is indicative of the bending stiffness of the structures. The term “indicative” covers various embodiments, for example an embodiment wherein the collapse rate is either 0 or 1, indicating that the stiffness is sufficient to withstand a process that exhibits a similar influence on the test patterns as the e-beam. According to other embodiments, the e-beam is configured to induce a variety of collapse rates (0<collapse rate<1) of the same structures distributed across the substrate or from wafer to wafer. The latter embodiment can be applied for determining the patterning process non-uniformity or variations in terms of the litho and etch process for producing the test patterns. This information can in turn be used to eliminate the non-uniformity from pattern collapse measurements applied to evaluate the uniformity of another process, such as a wet cleaning process. In other embodiments, the e-beam is configured to induce and compare the collapse rates of structures with different geometry (such as different critical dimensions (CDs), gaps and heights) or different materials. This enables a comparison of the relative strength of any high aspect ratio structures.

Throughout this specification and in the appended claims, the term “high aspect ratio nanosized structures” refers to structures characterized by an in-plane critical dimension, for example a diameter or a width, in the order of a few nanometers up to a few tens of nanometers and a height that is significantly higher than the in-plane critical dimension. According to some embodiments, the height is at least 3 times higher than the in-plane critical dimension. According to further embodiments, the height is at least 5 times or at least 10 times higher than the in-plane critical dimension.

The disclosure is in particular related to a method for evaluating the bending stiffness of high aspect ratio nanosized structures arranged in a plurality of test patterns produced by lithography and etching in a respective plurality of different areas of a semiconductor substrate, each test pattern comprising a regular array of the structures, the method comprising the steps of:
scanning the regular arrays in the multiple test patterns by an electron beam produced according to the same set of beam conditions for each array,
from the scanning of the arrays, deriving images of the arrays in the respective test patterns by electron beam microscopy,
determining from each of the images an e-beam induced collapse rate, being a value between 0 and 1 representative of the percentage of structures in each array which have collapsed under the influence of the electron beam scanning, and wherein the e-beam induced collapse rate is indicative of the bending stiffness of the structures.

According to an embodiment, one or more parameters which define the array exhibit a variation between different test patterns as produced in respective different areas of the substrate, and the beam conditions are configured so that the variation leads to a corresponding variation in the collapse rate.

According to an embodiment, the one or more parameters exhibiting a variation are one or more of the following: an in-plane dimension of the structures, the height of the structures, the material of the structures, the gap between adjacent structures in the array.

According to an embodiment, the beam conditions are configured to match the effect in terms of the collapse rate of the structures in the array, of a semiconductor process applicable on the substrate.

According to an embodiment, the arrays in the test patterns are produced on the basis of the same design pattern formed of an array of structures characterized by one or more in-plane design dimensions, and the test patterns are produced by applying the same etch recipe.

According to an embodiment, each test pattern produced respectively in the plurality of areas of the substrate comprises multiple regular arrays produced on the basis of multiple design patterns characterized by respective multiple values of at least one in-plane design dimension and/or of the gap between adjacent structures, wherein the multiple values are distributed across a given range.

According to an embodiment, the collapse rates are recorded in the form of curves expressing the collapse rate as a function of the multiple values in a central, middle and edge area of the substrate.

According to an embodiment, the test patterns are produced using a mask configured to print a device pattern on a plurality of die areas on the substrate, the mask comprising a metrology target included in the field of view of a lithographic tool used for printing the device pattern, and the target is configured to produce the test patterns in the respective die areas.

According to an embodiment, the numerical value of the bending stiffness is derived from the e-beam induced collapse rate, based on a previously determined relation between the collapse rate and the stiffness.

The disclosure is also related to a method for evaluating a process uniformity of a process that is applicable on a semiconductor substrate, the method comprising the steps of:
producing a plurality of test patterns by a lithography and etch sequence in a respective plurality of different areas of the substrate, each pattern comprising a regular array of high aspect ratio nanosized structures wherein the arrays are produced on the basis of the same design pattern and wherein the test patterns are produced by applying the same etch recipe, and wherein the lithography and etch sequence exhibits a degree of non-uniformity so that one or more parameters which define the arrays exhibit a variation between different test patterns as produced in respective different areas of the substrate,
applying a method according to the disclosure on the plurality of arrays, to thereby obtain a plurality of collapse rate measurements for the respective plurality of arrays,
performing the process on:
   the substrate wherein the test patterns further comprise at least one duplicate of the array in the respective plurality of different areas, or
   on another substrate of the same size as the substrate and comprising duplicates of the array in the same plurality of different areas,
determining the collapse rate induced by the process on images of the respective duplicates of the array,
using the e-beam induced collapse rates in order to eliminate the effect of the non-uniformity of the lithography and etch sequence from the process-induced collapse rates.

According to an embodiment of the method for evaluating a process uniformity:
each test pattern comprises multiple regular arrays produced on the basis of multiple design patterns of the arrays characterized by respective multiple values of an in-plane design dimension, wherein the values are distributed across a given range,
the e-beam induced collapse rates are recorded in the form of curves expressing the collapse rate as a function of the design dimension in a central, middle and edge area of the substrate,
the process-induced collapse rates are also recorded in the form of curves expressing the collapse rate as a function of the design dimension in the central, middle and edge area of the substrate,
the process uniformity is evaluated on the basis of whether or not a horizontal shift between the curves corresponding to the center, middle, and edge areas is the same for the process-induced collapse rates as for the e-beam induced collapse rates.

According to embodiments of the method for evaluating a process uniformity, the process is a wet cleaning process or a deposition process.

### BRIEF DESCRIPTION OF THE DRAWINGS

FIG. 1A illustrates the capability of scanning an electron beam across a regular pattern of nanosized pillars to induce pattern collapse, according to example embodiments.

FIG. 1B illustrates the capability of scanning an electron beam across a regular pattern of nanosized pillars to induce pattern collapse, according to example embodiments.

FIG. 2A and illustrates the capability of scanning an electron beam across an array of nanosized fins to induce pattern collapse, according to example embodiments.

FIG. 2B illustrates the capability of scanning an electron beam across an array of nanosized fins to induce pattern collapse, according to example embodiments.

FIG. 3 illustrates the result of measurements of the e-beam induced collapse rate of nanosized pillars as a function of the bending stiffness of the pillars, according to example embodiments.

FIG. 4A illustrates a process wafer provided with printed and etched metrology targets suitable for use in a method, according to example embodiments.

FIG. 4B illustrates a process wafer provided with printed and etched metrology targets suitable for use in a method, according to example embodiments.

FIG. 4C illustrates a process wafer provided with printed and etched metrology targets suitable for use in a method, according to example embodiments.

FIG. 5A illustrates a calibration procedure, according to example embodiments.

FIG. 5B illustrates a calibration procedure, according to example embodiments.

### DETAILED DESCRIPTION

Pattern collapse in a regular array of high aspect ratio nanosized structures can be induced deliberately by scanning the array with an electron beam in a scanning electron microscope. Reference is made for example to document “Mechanism of nanostructure movement under an electron beam and its application in patterning,” Seminara et al., Physical Review B 83, 235438 (2011). The beam conditions can be chosen so that at least a portion of the structures in the array are bent or deflected by the interaction with the beam. The image obtained from the microscope reveals the collapsed structures and enables counting them to obtain a value referred to as the collapse rate, which may be expressed as a number between 0 and 1 defined as the ratio of the number of collapsed structures in a given array to the total number of structures in the array.

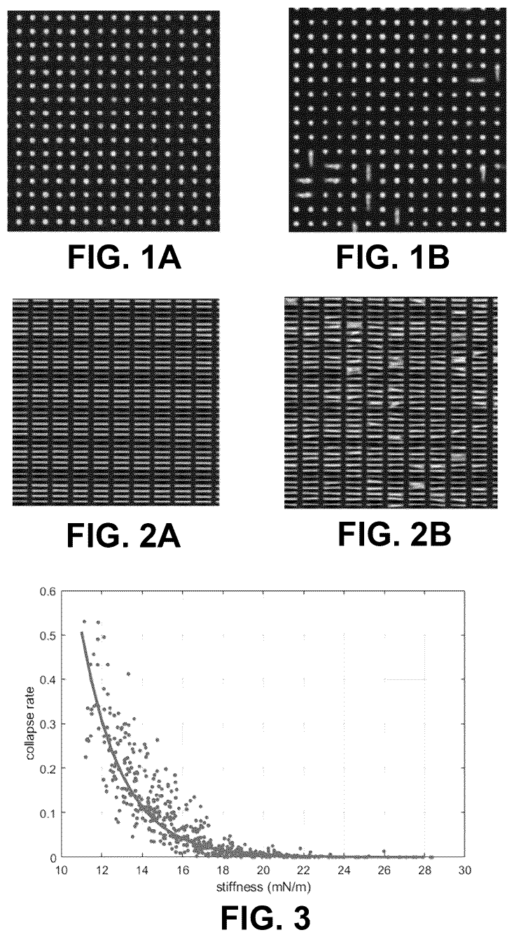

FIGS. 1A and 1B illustrate an example of a SEM image before and after pattern collapse in an array of nanosized pillars. The first image is obtained by applying an e-beam having insufficient power to cause pattern collapse. Pattern collapse as illustrated in the second image can be induced, for example by raising the beam current and/or the exposure time. As shown in FIGS. 2A and 2B, the same effect can be obtained in an array of fin-shaped nanosized structures.

This phenomenon of deliberately induced pattern collapse is applied in the method of the disclosure, in order to quantify differences in the bending stiffness of high aspect ratio nanostructures across a substrate and/or between substrates. FIG. 3 illustrates a graph comprising a number of data points, each data point representing the result of measurements on an array of nanosized pillars similar to the array illustrated in FIG. 1A, wherein the average bending stiffness of the pillars in the array varied within a given range. The Y-axis of the graph represents the collapse rate as a consequence of scanning the array by the same e-beam in terms of the e-beam conditions. The X-axis represents the average bending stiffness of the pillars in the arrays. The pillars were modeled using a mechanical model based on a tapered cylindrical profile obtained by scatterometry measurements performed on the arrays. The graph shows that there is a correlation between the e-beam induced collapse rate and the average stiffness of the pillars. Under the same e-beam conditions, higher collapse rates can be observed for structures with lower average bending stiffness.

According to example embodiments, test patterns formed of high aspect ratio nanosized structures are produced in different areas of a substrate. Each test pattern comprises at least one regular array of the structures. Arrays of the test patterns produced respectively in the areas are scanned by an electron beam produced according to the same set of beam conditions for each scanning. These beam conditions include the following: beam current, exposure time (may also be expressed as number of frames), field of view, landing energy, scanning rate, interlace. The arrays are configured to enable determining an e-beam induced collapse rate between 0 and 1 with a sufficiently high resolution to be able to measure a variation of the collapse rate within the range of 0 to 1. This may mean that the number of structures in each array is sufficiently high. An optimized number may differ depending on the shape and dimensions of the structures. Suitable numbers may for example range from about 100 to several hundred, as illustrated in FIGS. 1A-2B. The arrays may be rectangular arrays as illustrated in FIGS. 1A-2B, or any other type of regular array, for example an array of structures ordered according to a hexagonal packing arrangement.

From the scanning of the arrays in the different areas of the substrate, images of the arrays are derived by electron beam microscopy, and the collapse rate is determined from each image by counting the number of collapsed structures. The arrays are produced by lithography and etching according to a given set of design dimensions, including the in-plane dimensions of the structures in the array, the height of the structures and the gap between adjacent structures.

According to some embodiments, the test patterns are obtained by printing and etching the same pattern multiple times in different areas across the surface of the substrate, applying the same lithographic and etch conditions in each area, wherein at least one array in each test pattern (i.e. in each area of the substrate) is defined by the same set of design dimensions, including in-plane dimensions and height of the structures.

The repeated test pattern could for example be a large array of the same structures, with a constant gap in between adjacent structures. The dimensions of the array could be in the order of tens of micrometers. This large array thereby comprises multiple duplicates of the same smaller array comprising for example a few hundred structures, so that a collapse rate measurement can be done on a number of the multiple duplicates.

According to another embodiment, the repeated test pattern may include multiple arrays defined by different in-plane design dimensions, for example different design widths of an array of fin-shaped structures, or different gaps between adjacent structures.

According to other embodiments, the test patterns produced in the different areas may differ in terms of the type of structures, their geometry and/or the material of the structures. This could be achieved by applying different lithographic and/or etch conditions in one or more of the different areas, and/or by applying different lithographic masks for producing the different test patterns, and/or by producing one or more of the different test patterns in areas consisting of different materials.

The determination of the collapse rates on one or more arrays within the test patterns enables to evaluate the bending stiffness of the structures included in the test patterns. The term “evaluate” includes a number of embodiments and is not limited to the actual numerical determination of the bending stiffness. The latter may be possible if the relation between the collapse rate and the stiffness has been previously determined, for example in the form of a curve as shown in FIG. 3. In such a case, this curve can be used to derive the stiffness from a measurement of the e-beam induced collapse rates.

However, the method is applicable also when the actual stiffness values are not known, for example if a mechanical model of the structures is not available. One way of applying the method in this way is to verify whether the structures in the test pattern can withstand a particular semiconductor process, for example a wet cleaning step, without actually performing the process. As stated in the introduction, wet cleaning processes can induce pattern collapse in a regular array of high aspect ratio nanosized structures. This may also be the case for other processes. For example certain deposition processes such as flowable chemical vapor deposition (CVD) may also cause pattern collapse.

According to an embodiment, the e-beam conditions are selected to match the effect of a given process on a test pattern comprising an array characterized by a given set of design dimensions. By applying these e-beam conditions to various test patterns distributed across a wafer, it can be verified whether or not these test patterns are able to withstand the corresponding process by evaluating the e-beam induced collapse rates. If the collapse rates are zero across the wafer, the process can be applied. If the collapse rates are higher than zero in at least some areas of the wafer, another process should be selected.

Another application of the method is to assess and compare the relative strength of structures with different geometries. For example, applying the same e-beam conditions to different structures with unknown mechanical properties allows for a rapid assessment of their relative strength compared to a reference structure.

According to other embodiments, the e-beam conditions are selected in order to reveal a variation of the stiffness of the structures across a substrate. When a regular array of structures characterized by the same in-plane design dimensions is reproduced several times on a wafer, a deviation from one or more of the in-plane design dimensions may be inevitable and this deviation may be different in different areas of the substrate. Non-uniform etching could also cause variations in structure heights. This dimensional difference causes a difference in the bending stiffness of the structures, and it is therefore important for designers to be able to quantify this difference.

According to some embodiments therefore, the beam conditions are configured so that the collapse rate of at least one array of the test pattern that is reproduced according to the same design dimensions in different areas of the substrate falls within a suitable range (e.g., between 0 and 1, such as between 0.2 and 0.8). In other words, e-beam conditions according to these embodiments may enable sufficient sensitivity to compare the collapse rate variations for measurements across the wafer or from wafer to wafer.

The electron beam conditions which have an impact on the collapse rate include: beam current, exposure time, field of view, landing energy, scanning rate. Selecting the beam conditions for a given purpose, e.g. to reveal a stiffness variation, or to match the effect of a given process may therefore be done by setting or changing one or more of these conditions.

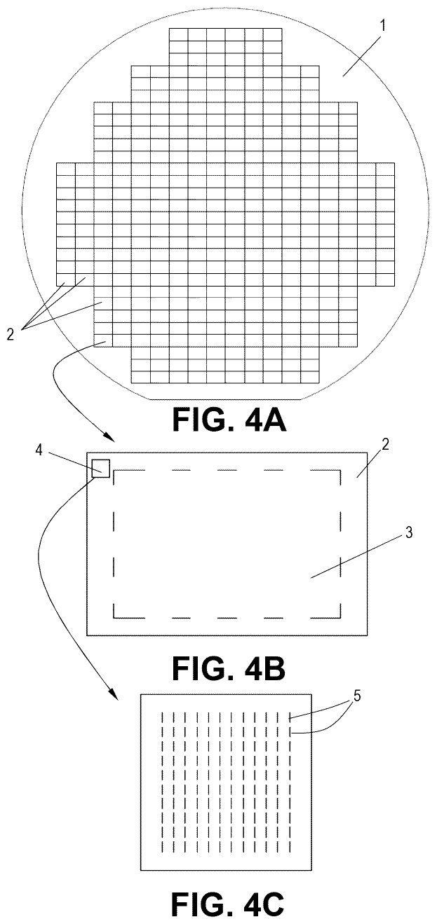

According to some embodiments, the same test pattern is part of a metrology target included in the field of view of a lithographic tool used for producing multiple semiconductor dies on a semiconductor wafer. FIG. 4A illustrates a process wafer 1 which may be a silicon wafer, for example a standard 300 mm process wafer. Semiconductor dies 2 are produced on multiple dedicated areas of the wafer. One die area is enlarged and represented in FIG. 4B. In a central portion 3 of the die area 2, a given layout of active devices such as transistors and diodes is fabricated by a sequence of process steps including lithography and etch steps configured to produce regular arrays of high aspect ratio nanostructures as described above. Metrology targets may be included in a lithographic mask designed for the production of such regular arrays. The targets are included in the field of view of the die but outside the active device area 3, for example in the upper left corner of the die area 2, as illustrated in FIG. 4A.

A metrology target applicable in example methods may include a test pattern in the form of one or more regular arrays of high aspect ratio nanostructures. An example of such a target 4 is illustrated in the enlarged image shown in FIG. 4C. The target is designed to produce an array of fins 5 of particular design dimensions, in terms of the width and length of the fins, and the gap between adjacent parallel fins. These dimensions are representative of the dimensions of arrays included in the active area 3 of the die. The CD of the fins is defined as the width of the fins. In the example shown, the target comprises a single array characterized by a single design CD, but the target could include multiple arrays characterized by the same or different design CDs and possibly different fin lengths and gaps. As stated above, the lithography and etch processes may exhibit a degree of non-uniformity across a wafer, leading to a deviation of the actual CD of the printed and etched structures from the design CD. This in turn leads to a variation in the bending stiffness of the fins.

According to some embodiments, this variation is quantified by scanning the target array 4 in each die area 2 by an electron beam, after producing the array on the wafer by lithography and etching. The beam conditions are chosen so that the beam induces a measurable difference of the collapse rate as a function of a difference in the actual CD across the wafer. The collapse rate is measured on images obtained from scanning the target patterns in a SEM tool.

From the respective images of the target arrays, the collapse rates are determined by counting the number of collapsed fins in each image. The collapse rate may be mapped on the various dies of the wafer, yielding a map that reveals differences in the bending stiffness of structures in the active areas which have the same or similar design CDs and which are arranged in arrays similar to the array included in the target 4.

One useful application of example embodiments is related to the determination of the process uniformity across a wafer, of semiconductor processing steps performed on the wafer. For example, the effect of wet cleaning steps should be as uniform as possible, i.e. the cleaning action should be the same in every area of the wafer. As stated in the introduction, wet cleaning steps may cause pattern collapse, therefore measuring the collapse rate of test patterns formed of high aspect ratio nanosized structures is one way of determining the process uniformity, after the process has been executed on the wafer. However, due to the variation of the dimensions of the structures across the wafer, it is difficult to correctly interpret the collapse rate measurements. The method of some embodiments provides the possibility of determining this variation before performing the cleaning process, and to thereby determine a baseline correction that is to be applied to the collapse rates induced by the cleaning process. The method of some embodiments thereby allows to calibrate the wafer in terms of the intrinsic bending stiffness variation, so that the influence of the variation can be eliminated from the collapse rates induced by a processing step. For example, a metrology target could be provided comprising a large micrometer-sized regular array of the same nanosized fins. Within this large array, two smaller arrays of the same size and the same number of structures can be selected. The first of these two smaller arrays could be used to determine the collapse rates by e-beam in accordance with example embodiments in order to determine the baseline correction for bending stiffness of the structures, while the second of the two smaller arrays can be used to determine the collapse rate induced by the process, for example a wet cleaning process.

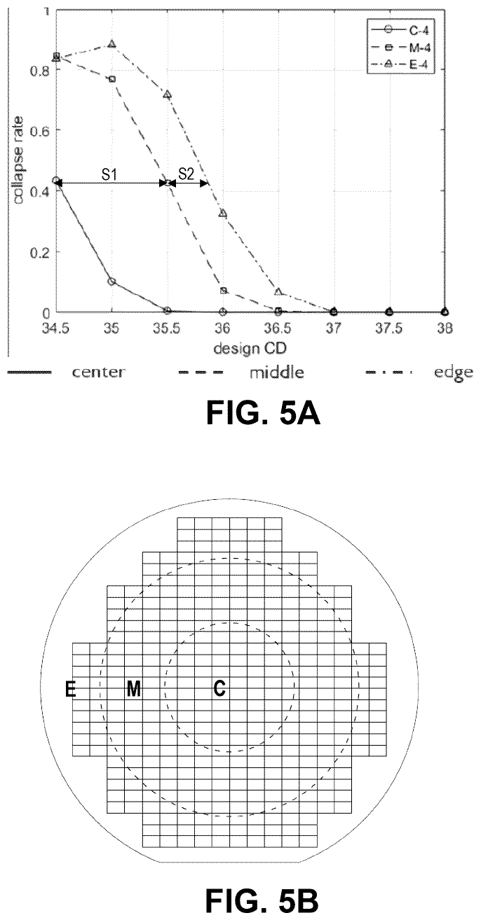

The calibration described in the previous paragraph is based on only one design CD and could therefore provide insufficient information on the process uniformity for other design CD values. An example of a more advanced baseline calibration is illustrated in FIGS. 5A and 5B. In each die area of a wafer, a plurality of fin arrays is included in the test pattern, characterized by different design CDs distributed regularly across a given range, for example from 34 nm to 38 nm in steps of 0.5 nm. The fin arrays could be included in metrology targets 4 distributed across the wafer as illustrated in FIGS. 4A to 4C, or a test wafer could be designed comprising only the test patterns in the respective die areas 2. In the latter case, the range of the design CDs could be applied for different fin lengths and/or for different pitches of the array to provide even more variables for which the process uniformity can be evaluated.

Having reproduced the fin arrays in each die area by lithography and etching, the various arrays are imaged by SEM and the collapse rate is measured as a function of the design CD. This is done using e-beam conditions which enable to measure a wide range of collapse rates as a function of the design CDs in at least one area of the wafer.

The result of such a calibration is illustrated in FIG. 5A, for the above-named range of 34-38 nm for the design CD and for a given value of the fin lengths and pitch. The collapse rate is determined in three radially adjacent areas of the wafer, designated as center, middle and edge, as illustrated in FIG. 5B by the abbreviations C, M and E. The graph in FIG. 5A shows the relation between the measured e-beam induced collapse rates in the three areas, and the design CDs included in the test arrays. It is seen that for a collapse rate of about 0.45, there are significant shifts S1 and S2 of the curves in the center and edge areas of the wafer relative to the curve in the middle area of the wafer.

The same curves can be obtained following a wet cleaning step. If the same shifts S1 and S2 are observed after cleaning, the conclusion is that the cleaning process is uniform in the center, middle and edge areas. Another way of determining the uniformity is by applying the inverse shifts -S1 and -S2 to the edge and center curves obtained after cleaning, and verifying whether the shifted curves coincide with the middle curve. If this is the case, the process is uniform. Any remaining shifts between the curves indicate a lack of process uniformity.

The calibration procedure described above is performed on a substrate and the result can be used to assess process non-uniformity on the substrate itself, as described. However, the result can also be used on another substrate for assessing the uniformity of the same process on the other substrate. The other substrate is of the same size of the initial substrate and provided with duplicates of the regular array or arrays used in the calibration procedure, and produced in the same areas as the initial substrate.

While embodiments have been illustrated and described in detail in the drawings and foregoing description, such illustration and description are to be considered illustrative or exemplary and not restrictive. Other variations to the disclosed embodiments can be understood and effected by those skilled in the art, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used. Any reference signs in the claims should not be construed as limiting the scope.

What is claimed is:

1. A method for evaluating a bending stiffness of high aspect ratio nanosized structures arranged in a plurality of test patterns produced by lithography and etching in a respective plurality of different areas of a semiconductor substrate, wherein each test pattern comprises a regular array of the high aspect ratio nanosized structures, and wherein the method comprises:
scanning the regular arrays in the plurality of test patterns by an electron beam produced according to a same set of beam conditions for each array;
from the scanning of the regular arrays, deriving images of the regular arrays in the respective test patterns by electron beam microscopy; and
determining from each of the images an e-beam induced collapse rate, wherein the e-beam induced collapse rate comprises a value between 0 and 1 representative of a percentage of structures in each array that have collapsed under an influence of the electron beam scanning, and wherein the e-beam induced collapse rate is indicative of a bending stiffness of the structures.

2. The method according to claim 1, wherein one or more parameters define the array, wherein the one or more parameters exhibit a variation between different test patterns as produced in respective different areas of the semiconductor substrate, and wherein the beam conditions are configured so that the variation leads to a corresponding variation in the collapse rate.

3. The method according to claim 2, wherein the one or more parameters comprise an in-plane dimension of the structures, heights of the structures, materials of the structures, or gaps between adjacent structures in the array.

4. The method according to claim 1, wherein the beam conditions are configured to match effect in terms of the collapse rate of the structures in the array of a semiconductor process applicable on the semiconductor substrate.

5. The method according to claim 1, wherein the arrays in the test patterns are produced based on a same design pattern formed of an array of structures characterized by one or more in-plane design dimensions, and wherein the test patterns are produced by applying a same etch recipe.

6. The method according to claim 5, wherein each test pattern produced respectively in the plurality of areas of the semiconductor substrate comprises multiple regular arrays produced using multiple design patterns characterized by respective multiple values of at least one in-plane design dimension or of gaps between adjacent structures, and wherein the multiple values are distributed across a given range.

7. The method according to claim 6, wherein the collapse rates are recorded as curves expressing the collapse rate as a function of the multiple values in a central area of the semiconductor substrate, middle area of the semiconductor substrate, and edge area of the semiconductor substrate.

8. The method according to claim 1, wherein the test patterns are produced using a mask configured to print a device pattern on a plurality of die areas on the semiconductor substrate, wherein the mask comprises a metrology target included in a field of view of a lithographic tool used for printing the device pattern, and wherein the metrology target is configured to produce the test patterns in the respective die areas.

9. The method according to claim 1, wherein a numerical value of the bending stiffness is derived from the e-beam induced collapse rate based on a previously determined relation between the collapse rate and the bending stiffness.

10. A method for evaluating a process uniformity of a first process that is applicable on a semiconductor substrate, the method comprising:
producing a plurality of test patterns by a lithography and etch sequence in a respective plurality of different areas of the semiconductor substrate, wherein each test pattern comprises a regular array of high aspect ratio nanosized structures, wherein the regular arrays are produced using a same design pattern, wherein the test patterns are produced by applying a same etch recipe, and wherein the lithography and etch sequence exhibits a degree of non-uniformity so that one or more parameters which define the regular arrays exhibit a variation between different test patterns as produced in respective different areas of the semiconductor substrate;
applying a second process for evaluating a bending stiffness of the high aspect ratio nanosized structures to the regular arrays to obtain a plurality of collapse rate measurements for the regular arrays, wherein the second process comprises:
scanning the regular arrays in the plurality of test patterns by an electron beam produced according to a same set of beam conditions for each array;
from the scanning of the regular arrays, deriving images of the regular arrays in the respective test patterns by electron beam microscopy; and
determining from each of the images an e-beam induced collapse rate, wherein the e-beam induced collapse rate comprises a value between 0 and 1 representative of a percentage of structures in each array that have collapsed under an influence of the electron beam scanning, wherein the e-beam induced collapse rate is indicative of a bending stiffness of the structures, wherein one or more parameters define the array, wherein the one or more parameters exhibit a variation between different test patterns as produced in respective different areas of the semiconductor substrate, and wherein the beam conditions are configured so that the variation leads to a corresponding variation in the collapse rate;
performing the first process on:
the substrate, wherein the test patterns further comprise at least one duplicate of the array in the respective plurality of different areas; or
on another substrate of a same size as the substrate and comprising duplicates of the array in the same plurality of different areas;
determining the collapse rate induced by the first process on images of the respective duplicates of the array; and
using the e-beam induced collapse rates in order to eliminate an effect of the non-uniformity of the lithography and etch sequence from the process-induced collapse rates.

11. The method according to claim 10,
wherein each test pattern comprises multiple regular arrays produced based on multiple design patterns of the arrays characterized by respective multiple values of an in-plane design dimension,
wherein the values are distributed across a given range,
wherein the e-beam induced collapse rates are recorded as curves expressing the collapse rate as a function of the design dimension in a central area of the semiconductor substrate, middle area of the semiconductor substrate, and edge area of the semiconductor substrate,
wherein the process-induced collapse rates are also recorded as curves expressing the collapse rate as a function of the design dimension in the central area of the semiconductor substrate, middle area of the semiconductor substrate, and edge area of the semiconductor substrate, and
wherein the process uniformity is evaluated based on whether a horizontal shift between the curves corresponding to the center area of the semiconductor substrate, middle area of the semiconductor substrate, and edge area of the semiconductor substrate is the same for the process-induced collapse rates as for the e-beam induced collapse rates.

12. The method according to claim 10, wherein the method is a wet cleaning process or a deposition process.

13. The method according to claim 10, wherein the one or more parameters comprise an in-plane dimension of the structures, heights of the structures, materials of the structures, or gaps between adjacent structures in the array.

14. The method according to claim 10, wherein the beam conditions are configured to match effect in terms of the collapse rate of the structures in the array of a semiconductor process applicable on the semiconductor substrate.

15. The method according to claim 10, wherein the arrays in the test patterns are produced based on a same design pattern formed of an array of structures characterized by one or more in-plane design dimensions, and wherein the test patterns are produced by applying a same etch recipe.

16. The method according to claim 15, wherein each test pattern produced respectively in the plurality of areas of the semiconductor substrate comprises multiple regular arrays produced using multiple design patterns characterized by respective multiple values of at least one in-plane design dimension or of gaps between adjacent structures, and wherein the multiple values are distributed across a given range.

17. The method according to claim 16, wherein the collapse rates are recorded as curves expressing the collapse rate as a function of the multiple values in a central area of the semiconductor substrate, middle area of the semiconductor substrate, and edge area of the semiconductor substrate.

18. The method according to claim 10, wherein the test patterns are produced using a mask configured to print a device pattern on a plurality of die areas on the semiconductor substrate, wherein the mask comprises a metrology target included in a field of view of a lithographic tool used for printing the device pattern, and wherein the metrology target is configured to produce the test patterns in the respective die areas.

19. The method according to claim 10, wherein a numerical value of the bending stiffness is derived from the e-beam induced collapse rate based on a previously determined relation between the collapse rate and the bending stiffness.

20. A method comprising:
determining a first bending stiffness of first high aspect ratio nanosized structures arranged in a first test pattern produced by lithography and etching in a first area of a semiconductor substrate, wherein the first test pattern comprises a first regular array of the first high aspect ratio nanosized structures:
scanning the first regular array in the first test pattern by a first electron beam;
from the scanning of the first regular array, deriving a first image of the first regular array in the first test pattern by electron beam microscopy; and
determining from the first image a first e-beam induced collapse rate, wherein the first e-beam induced collapse rate comprises a first value between 0 and 1 representative of a percentage of structures in the first array that have collapsed under an influence of the first electron beam scanning, and wherein the first e-beam induced collapse rate is indicative of a bending stiffness of the first structures;
determining a second bending stiffness of second high aspect ratio nanosized structures arranged in a second test pattern produced by lithography and etching in a second area of a semiconductor substrate, wherein the second test pattern comprises a second regular array of the second high aspect ratio nanosized structures:
scanning the second regular array in the second test pattern by a second electron beam, wherein the second electron beam is produced according to a same set of beam conditions as the first electron beam;
from the scanning of the second regular array, deriving a second image of the second regular array in the second test pattern by electron beam microscopy; and
determining from the second image a second e-beam induced collapse rate, wherein the second e-beam induced collapse rate comprises a second value between 0 and 1 representative of a percentage of structures in the second array that have collapsed under an influence of the second electron beam scanning, and wherein the second e-beam induced collapse rate is indicative of a bending stiffness of the second structures; and
comparing:
the second bending stiffness to the first bending stiffness; or
the second e-beam induced collapse rate to the first e-beam induced collapse rate.
